(19) United States
(12) Patent Application Publication
(10) Pub. No.: US 2026/0367111 A1
(43) Pub. Date: Nov. 19, 2026

(54) ELECTRICALLY CONDUCTIVE PIN

(71) Applicant: AMST CO., LTD., Suwon-si (KR)

(72) Inventors: Byung Chang SONG, Suwon-si (KR); Tae Seung OH, Hwaseong-si (KR); Yun Hee SHIM, Suwon-si (KR); Mi Soon KANG, Hwaseong-si (KR); Soo Ho CHO, Hwaseong-si (KR)

(73) Assignee: AMST CO., LTD., Suwon-si (KR)

(21) Appl. No.: 19/712,047

(22) Filed: Jun. 18, 2026

Related U.S. Application Data
(63) Continuation of application No. PCT/KR2024/019675, filed on Dec. 4, 2024.

(30) Foreign Application Priority Data
Dec. 20, 2023 (KR) 10-2023-0187420

(51) Int. Cl. G01R 1/067

(52) U.S. Cl. CPC G01R 1/06733; G01R 1/06722; G01R 1/06755

(57) ABSTRACT

The present invention provides an electrically conductive pin with improved physical and electrical properties. This electrically conductive pin which is provided in an inspection apparatus that identifies whether an object to be inspected is defective, and which transmits an electrical signal to the object to be inspected includes: a first contact portion positioned at one end portion of the electrically conductive pin; a second contact portion positioned at the other end portion of the electrically conductive pin; an elastic portion which is positioned between the first contact portion and the second contact portion and can be compressed and stretched in the longitudinal direction; and a current transfer portion which is positioned to be spaced apart from the elastic portion in the thickness direction, and which transfers an electrical signal between the first contact portion and the second contact portion.

### CROSS-REFERENCE TO RELATED APPLICATIONS

The application claims priority to Korea patent application No. 10-2023-0187420, filed on Dec. 20, 2023, the entire contents of which are incorporated herein by reference.

### TECHNICAL FIELD

The present invention relates to an electrically conductive pin, and more specifically, to an electrically conductive pin with improved physical and electrical properties.

### BACKGROUND

An electrically conductive pin refers to a contact pin that can be used in inspection apparatuses such as probe cards or test sockets, which inspect test objects by coming into contact with them. Here, the electrically conductive pin serves the role of transmitting electrical signals between the test object and the inspection apparatus.

The method of inspecting the electrical characteristics of a semiconductor device is performed by applying electrical signals through a probe card or test socket equipped with multiple electrically conductive pins, which are brought into contact with a semiconductor wafer or semiconductor package (hereinafter referred to as the ‘inspection target’).

This method generally involves bringing the electrically conductive pins into contact with the inspection target to create a contact state, and further approaching in the same direction to cause elastic deformation of the electrically conductive pins (overdrive). As a result, multiple electrically conductive pins elastically deform and come into contact with the corresponding electrode pads of the inspection target.

Therefore, electrically conductive pins are required to have high durability to withstand repetitive electrode contact and elastic deformation, and high current-carrying capacity characteristics to fulfill their essential function of current transmission.

Meanwhile, electrically conductive pins manufactured through MEMS processes can be integrally formed, including an elastic portion, without having a separate elastic member for elastic deformation. In this regard, prior art document No. 10-2009-0117053 discloses a “vertical micro-contact probe with variable stiffness functionality.”

The prior art document describes a probe structure integrally formed, including an elastic portion. However, in the case of such a probe structure, if it is made of a material with high durability, the current-carrying capacity may decrease, and if it is made of a material with high current-carrying capacity, the durability may decrease. Additionally, due to the curved portion for forming the elastic portion, the electrical signal path becomes longer, resulting in reduced electrical signal transmission efficiency.

### Prior Art Documents

### Patent Documents

(Patent Document 1) Publication No. 10-2009-0117053 Published Patent Gazette

### SUMMARY

To solve the aforementioned problems, the present invention aims to provide an electrically conductive pin with improved physical and electrical properties.

To achieve the above-described objective, an electrically conductive pin according to an embodiment of the present invention is provided in an inspection apparatus for checking whether a test object is defective and transmitting an electrical signal to the test object, the electrically conductive pin comprising: a first contact portion located at one end of the electrically conductive pin; a second contact portion located at the other end of the electrically conductive pin; an elastic portion located between the first contact portion and the second contact portion and capable of compression and extension in a longitudinal direction; and a current transmission portion spaced apart from the elastic portion in a thickness direction and located between the first contact portion and the second contact portion to transmit an electrical signal.

Also, in an embodiment of the present invention, the elastic portion may comprise: a plurality of elastic members, one end and the other end of which are respectively connected to the first contact portion and the second contact portion, and which are spaced apart from each other in a thickness direction.

Also, in the embodiment of the present invention, the elastic portion may further comprise a connecting member connecting at least two of the plurality of elastic members to each other.

Also, in an embodiment of the present invention, the current transmission portion comprises a bent region bent in a width direction in at least a portion thereof, and the bent region can induce deformation of the current transmission portion in the width direction.

Also, in an embodiment of the present invention, the current transmission portion has one end connected to one side in a width direction of the first contact portion, and the other end can be connected to one side in a width direction of the second contact portion.

Also, in an embodiment of the present invention, the current transmission portion may have one end connected to one side in a width direction of the first contact portion, and the other end connected to the other side in a width direction of the second contact portion.

Also, in an embodiment of the present invention, the current transmission portion may have one end connected to a center side in a width direction of the first contact portion, and the other end connected to a center side in a width direction of the second contact portion.

Also, in an embodiment of the present invention, the current transmission portion may comprise: a first current transmission portion having one end and the other end connected to the first contact portion and the second contact portion, respectively; and a second current transmission portion spaced apart from the first current transmission portion in a thickness direction, and having one end and the other end connected to the first contact portion and the second contact portion, respectively.

Also, in an embodiment of the present invention, the current transmission portion may have one end connected to one of the first contact portion and the second contact portion, the other end spaced apart from the other of the first contact portion and the second contact portion, and the other end may be connected to the other when the elastic portion is compressed.

Also, in an embodiment of the present invention, the current transmission portion may be made of a material having greater electrical conductivity than the elastic portion.

The present invention has the effect of improving the durability of the electrically conductive pin while simultaneously enhancing the current carrying capacity by distinguishing the elastic portion and the current transmission portion.

In addition, the present invention has the effect of improving the signal transmission speed due to the shortening of the transmission line as the current carrying capacity is enhanced by the current transmission portion.

### BRIEF DESCRIPTION OF DRAWINGS

FIG. 1 is a diagram illustrating an electrically conductive pin according to an embodiment of the present invention.

FIGS. 2A and 2B are diagrams illustrating an electrically conductive pin according to an embodiment of the present invention.

FIGS. 3A and 3B are diagrams illustrating an electrically conductive pin comprising a current transmission portion according to an embodiment of the present invention.

FIGS. 4A and 4B are diagrams illustrating an electrically conductive pin comprising a current transmission portion according to an embodiment of the present invention.

FIGS. 5A and 5B are diagrams illustrating an electrically conductive pin comprising a current transmission portion according to an embodiment of the present invention.

FIGS. 6A and 6B are diagrams illustrating an electrically conductive pin comprising a plurality of bent regions according to an embodiment of the present invention.

FIGS. 7A and 7B are diagrams illustrating an electrically conductive pin comprising a plurality of current transmission portions according to an embodiment of the present invention.

FIGS. 8A and 8B are diagrams illustrating an electrically conductive pin comprising a plurality of current transmission portions according to an embodiment of the present invention.

FIGS. 9A and 9B are diagrams illustrating an electrically conductive pin in which the current transmission portion and the second contact portion are spaced apart according to an embodiment of the present invention.

FIGS. 10A, 10B, and 10C are diagrams illustrating an electrically conductive pin comprising a connecting member according to an embodiment of the present invention.

FIGS. 11A and 11B are diagrams illustrating the A-A′ cross-section of FIG. 10A.

FIGS. 12A to 12G are diagrams illustrating the first contact portion and/or the second contact portion of an electrically conductive pin according to various embodiments of the present invention.

### DETAILED DESCRIPTION OF THE EMBODIMENTS

A person skilled in the art, even though not explicitly described or illustrated in this specification, can develop various devices that embody the principles of the invention and are included within the concept and scope of the invention. Furthermore, all conditional terms and embodiments listed in this specification are, in principle, explicitly intended only for the purpose of understanding the concept of the invention and should be understood as not being limited to the specifically enumerated embodiments and conditions.

The aforementioned objectives, features, and advantages will become more apparent through the following detailed description of the invention in conjunction with the accompanying drawings, thereby enabling a person skilled in the art to easily implement the technical idea of the invention.

The embodiments described in this specification will be explained with reference to cross-sectional views and/or perspective views, which are ideal illustrations of the invention. The sizes of the configurations shown in these drawings may be exaggerated for effective explanation of the technical content. The shapes of the illustrations may vary due to manufacturing techniques and/or tolerances.

While describing various embodiments, components performing the same function will be assigned the same names and reference numerals for convenience, even if the embodiments differ. The expression “at least one of A, B, and C” means one, two, or all three of A, B, and C. Additionally, in this specification, the thickness direction refers to the +x and/or −x directions, the width direction refers to the +y and/or −y directions, and the length direction refers to the +z and/or −z directions. Furthermore, for convenience, the description of configurations and operations already explained in other embodiments will be omitted. Also, expressions such as “first,” “second,” etc., are merely terms attached for convenience to explain multiple concepts and should not be interpreted as indicating specific configurations shown in specific positions in the drawings.

Hereinafter, an electrically conductive pin 10 according to an embodiment of the present invention will be described.

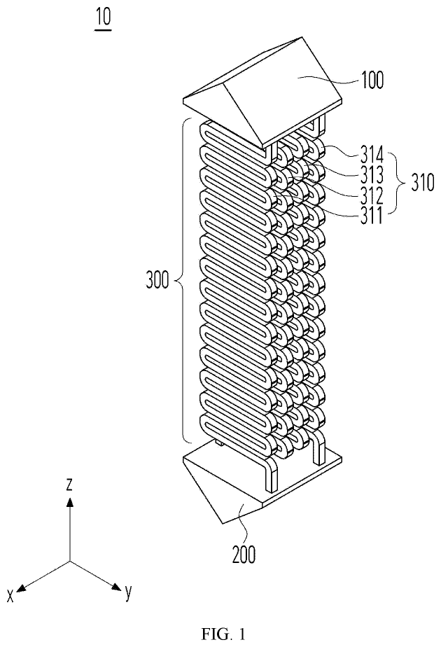

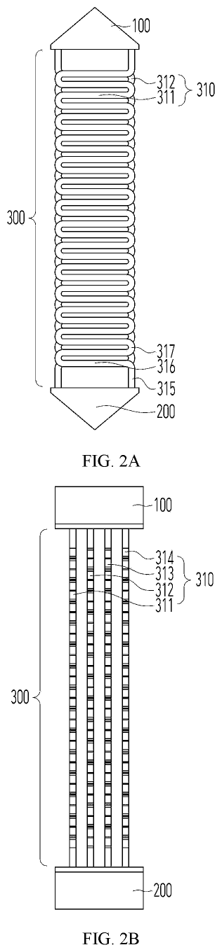

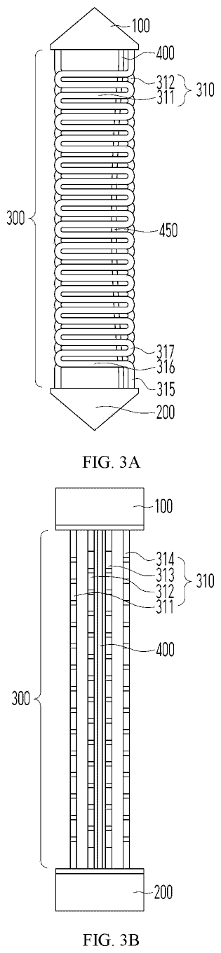

FIG. 1 illustrates an electrically conductive pin 10 according to an embodiment of the present invention. FIGS. 2A and 2B illustrate an electrically conductive pin 10 according to an embodiment of the present invention. FIGS. 3A and 3B illustrate an electrically conductive pin 10 including a current transmission portion 400 according to an embodiment of the present invention.

Referring to FIGS. 1 to 3B, the electrically conductive pin 10 according to an embodiment of the present invention may include a first contact portion 100 located at one end of the electrically conductive pin 10, a second contact portion 200 located at the other end of the electrically conductive pin 10, and an elastic portion 300 located between the first contact portion 100 and the second contact portion 200, which can be compressed and extended in the length direction. The electrically conductive pin 10 may further include a current transmission portion 400, which is spaced apart from the elastic portion 300 in the thickness direction and located between the first contact portion 100 and the second contact portion 200 to transmit electrical signals. The electrically conductive pin 10 may be provided in an inspection apparatus (not shown) for checking whether a test object (not shown) is defective and transmitting electrical signals to the test object.

The test object may be a semiconductor wafer and/or a semiconductor package. The inspection apparatus may be a probe card and/or a test socket. By transmitting current between the test object and the inspection apparatus through the electrically conductive pin 10, the inspection apparatus can inspect the electrical characteristics of the test object. Specifically, the electrically conductive pin 10 may contact or electrically connect to the electrode pads of the test object and the inspection apparatus to transmit current to the electrode pads and the inspection apparatus.

The first contact portion 100 may be located at one end of the electrically conductive pin 10. The second contact portion 200 may be located at the other end of the electrically conductive pin 10. The first contact portion 100 may contact or electrically connect to an electrode pad electrically connected to the circuit board of the inspection apparatus, and the second contact portion 200 may contact or electrically connect to an electrode pad electrically connected to the test object. Alternatively, the first contact portion 100 may contact or electrically connect to an electrode pad electrically connected to the test object, and the second contact portion 200 may contact or electrically connect to an electrode pad electrically connected to the circuit board.

The first contact portion 100 may be formed such that its horizontal cross-sectional area (xy-plane) decreases toward the end in the length direction, and the second contact portion 200 may be formed similarly. The first contact portion 100 and the second contact portion 200 may have a width in the region with the largest horizontal cross-sectional area that is greater than the width of the elastic portion 300, and a thickness in the region with the largest horizontal cross-sectional area that is greater than the thickness of the elastic portion 300.

However, the first contact portion 100 and the second contact portion 200 are not limited to the shapes shown in FIG. 1, and the shape in FIG. 1 can be considered as one example. The first contact portion 100 and/or the second contact portion 200 may be manufactured using a MEMS process, allowing them to be formed in various shapes.

The elastic portion 300 may be located between the first contact portion 100 and the second contact portion 200. The elastic portion 300 may be compressible and extendable in the length direction. The elastic portion 300 may compress the electrically conductive pin 10 in the length direction in an overdrive state and extend the electrically conductive pin 10 back in the length direction when the overdrive state is released.

Referring to FIGS. 2A and 2B, the elastic portion 300 may include at least one elastic member 310. For example, the elastic portion 300 may include a first elastic member 311, a second elastic member 312, a third elastic member 313, and a fourth elastic member 314. This is merely an example, and the elastic portion 300 may include fewer or more elastic members 310.

The elastic member 310 may have one end connected to the first contact portion 100 and the other end connected to the second contact portion 200. The elastic member 310 may include a coupling portion 315 connected to the first contact portion 100, a straight portion 316 connected to the coupling portion 315, and a curved portion 317 connected to the straight portion 316.

The elastic member 310 may include two coupling portions 315, with one coupling portion 315 located at one end connected to the first contact portion 100, and the other coupling portion 315 located at the other end connected to the second contact portion 200. The coupling portion 315 may extend in the length direction and connect to the first contact portion 100 and/or the second contact portion 200.

The elastic member 310 may include multiple straight portions 316, each of which may have one end and the other end connected to curved portions 317. However, the straight portions 316 located at both ends among the multiple straight portions 316 may have one end connected to a curved portion 317 and the other end connected to a coupling portion 315.

The elastic member 310 may include multiple curved portions 317, each of which may have one end and the other end connected to straight portions 316. The curved portion 317 can narrow or widen the angle and/or spacing between the straight portions 316 that are connected to both ends, thereby actively contracting or extending the electrically conductive pin 10.

The elastic portion 300 may include the first elastic member 311 and the second elastic member 312. In this case, the first elastic member 311 may have a first phase, and the second elastic member 312 may have a second phase.

Referring back to FIG. 1, the first phase of the first elastic member 311 is as follows:

The first elastic member 311 may have one end connected to one side in the width direction of the first contact portion 100. The first elastic member 311 may be connected to one surface (or lower surface) of the first contact portion 100. Here, one side in the width direction of the first contact portion 100 may refer to a position closer to the end of the first contact portion 100 encountered when proceeding in the width direction (y-axis) from the center.

The other end of the first elastic member 311 may be connected to one side in the width direction of the second contact portion 200. The first elastic member 311 may be connected to one surface (or upper surface) of the second contact portion 200. Here, one side in the width direction of the second contact portion 200 may refer to a position with the same y-axis coordinate as one side in the width direction of the first contact portion 100.

In other words, the coupling portion 315 located at one end of the first elastic member 311 may be connected to one side of the first contact portion 100, and the coupling portion 315 located at the other end of the first elastic member 311 may be connected to one side of the second contact portion 200.

Referring again to FIG. 1, the second phase of the second elastic member 312 is as follows:

The second elastic member 312 may have one end connected to the other side in the width direction of the first contact portion 100. The second elastic member 312 may be connected to one surface (or lower surface) of the first contact portion 100. Here, the other side in the width direction of the first contact portion 100 may refer to a position closer to the end of the first contact portion 100 encountered when proceeding in the width direction (y-axis) from the center. Additionally, one side and the other side of the first contact portion 100 may refer to positions equidistant from the center in opposite directions along the xz-plane in the width direction.

The other end of the second elastic member 312 may be connected to the other side in the width direction of the second contact portion 200. The second elastic member 312 may be connected to one surface (or upper surface) of the second contact portion 200. Here, the other side in the width direction of the second contact portion 200 may refer to a position with the same y-axis coordinate as the other side in the width direction of the first contact portion 100.

In other words, the coupling portion 315 located at one end of the second elastic member 312 may be connected to the other side of the first contact portion 100, and the coupling portion 315 located at the other end of the second elastic member 312 may be connected to the other side of the second contact portion 200.

Unlike FIG. 1, the first elastic member 311 may have one end connected to one side of the first contact portion 100 and the other end connected to the other side of the second contact portion 200, while the second elastic member 312 may have one end connected to the other side of the first contact portion 100 and the other end connected to one side of the second contact portion 200.

When the elastic portion 300 includes only one elastic member 310, buckling in the width direction may occur when the electrically conductive pin 10 is compressed. Additionally, when the elastic portion 300 includes two elastic members 310 with the same phase, buckling in the width direction may occur when the electrically conductive pin 10 is compressed.

The electrically conductive pin 10 according to an embodiment of the present invention can prevent buckling in the width direction even when the electrically conductive pin 10 is compressed, as the first elastic member 311 and the second elastic member 312 are connected to the first contact portion 100 and the second contact portion 200, respectively, while having different phases.

In other words, even when the elastic portion 300 undergoes repeated elastic deformation, the electrically conductive pin 10 can reduce concerns about wear and damage. Even when the electrically conductive pin 10 is provided in inspection apparatuses such as guide plates and test sockets, wear and damage due to buckling can be prevented.

Referring to FIGS. 1 and 2B, the elastic portion 300 may include the first elastic member 311 to the fourth elastic member 314. The first elastic member 311 and the fourth elastic member 314 may have the first phase, and the second elastic member 312 and the third elastic member 313 may have the second phase. In this case, the elastic portion 300 may include the first elastic member 311, the second elastic member 312, the third elastic member 313, and the fourth elastic member 314 in order in the thickness direction. The first elastic member 311 and the fourth elastic member 314 may be located on the outer side in the thickness direction, while the second elastic member 312 and the third elastic member 313 may be located on the inner side in the thickness direction.

Alternatively, the first elastic member 311 to the fourth elastic member 314 may each have the first phase or the second phase in various combinations. In other words, the elastic portion 300 may include multiple elastic members 310, each having the first phase or the second phase.

The multiple elastic members 310 may be spaced apart from each other in the thickness direction. The multiple elastic members 310 may be independently compressible and extendable.

By being spaced apart from each other, the elastic members 310 do not cause friction with nearby elastic members 310 during compression and extension, thereby increasing durability and improving the physical properties of the electrically conductive pin 10.

By being independently spaced apart, the multiple elastic members 310 can increase current-carrying capacity due to reduced skin effect compared to when they are in contact with each other, thereby improving the electrical properties of the electrically conductive pin 10.

Referring to FIGS. 3A and 3B, the current transmission portion 400 may be spaced apart from the elastic portion 300 in the thickness direction. The current transmission portion 400 may transmit electrical signals between the first contact portion 100 and the second contact portion 200.

The electrically conductive pin 10 may be composed of copper (Cu), silver (Ag), gold (Au), rhodium (Rd), platinum (Pt), iridium (Ir), palladium (Pd), nickel (Ni), cobalt (Co), manganese (Mn), tungsten (W), phosphorus (P), or alloys thereof. Additionally, the electrically conductive pin 10 may be composed of palladium-cobalt (PdCo) alloy, palladium-nickel (PdNi) alloy, nickel-phosphorus (NiP) alloy, nickel-manganese (NiMn) alloy, nickel-cobalt (NiCo) alloy, nickel-boron (NiB) alloy, or nickel-tungsten (NiW) alloy. However, the material of the electrically conductive pin 10 is not limited to the aforementioned examples.

The current transmission portion 400 may be made of a material with greater electrical conductivity than the elastic portion 300. The elastic portion 300 may be made of a material with greater wear resistance than the current transmission portion 400.

For example, when the elastic portion 300 is made of a nickel-cobalt (NiCo) alloy material, the current transmission portion 400 may be made of a gold (Au) material. However, the aforementioned materials are merely examples and are not limited thereto. The current transmission portion 400 may adopt any material with greater electrical conductivity than the elastic portion 300, and the elastic portion 300 may adopt any material with greater wear resistance than the current transmission portion 400.

Since the current transmission portion 400 has greater electrical conductivity than the elastic portion 300, the electrically conductive pin 10 can form a current path through the current transmission portion 400, achieving higher electrical conductivity and improving electrical signal transmission efficiency.

Specifically, since the current transmission portion 400 has greater electrical conductivity than the elastic portion 300, it can guide current to move through the current transmission portion 400. Additionally, since the current transmission portion 400 has a shorter signal transmission path than the elastic portion 300, it can further improve the current movement speed.

The electrically conductive pin 10 according to an embodiment of the present invention can form a shorter current path through the current transmission portion 400, which has greater electrical conductivity than the elastic portion 300, thereby increasing current-carrying capacity and improving electrical properties. Furthermore, since the elastic portion 300 has greater wear resistance than the current transmission portion 400, the electrically conductive pin 10 can increase durability and improve physical properties.

The current transmission portion 400 may include a bent region 450 that is bent in the width direction in at least a part thereof. The bent region 450 may induce deformation of the current transmission portion 400 in the width direction. By inducing elastic deformation of the current transmission portion 400 in the width direction, the bent region 450 can prevent contact with the elastic portion 300, which is spaced apart in the thickness direction.

The electrically conductive pin 10 according to an embodiment of the present invention can prevent wear and damage even under repeated deformation by inducing the current transmission portion 400 to elastically deform in the width direction.

The current transmission portion 400 may be provided in plurality. The multiple current transmission portions 400 may be spaced apart from each other in the thickness direction. The current transmission portion 400 may have one end connected to the first contact portion 100 and the other end connected to the second contact portion 200.

The electrically conductive pin 10 according to an embodiment of the present invention can improve physical properties, as the multiple current transmission portions 400 are spaced apart from each other in the thickness direction and are also spaced apart from the elastic portion 300 in the thickness direction, so that mutual friction does not occur even when the elastic portion 300 undergoes elastic deformation.

The electrically conductive pin 10 according to an embodiment of the present invention is configured such that one end and the other end of the current transmission portion 400 are connected to the first contact portion 100 and the second contact portion 200, respectively. By reducing end wear of the current transmission portion 400 in cases where contact and separation are repeatedly performed based on a state in which either side is separated, the physical properties can be improved.

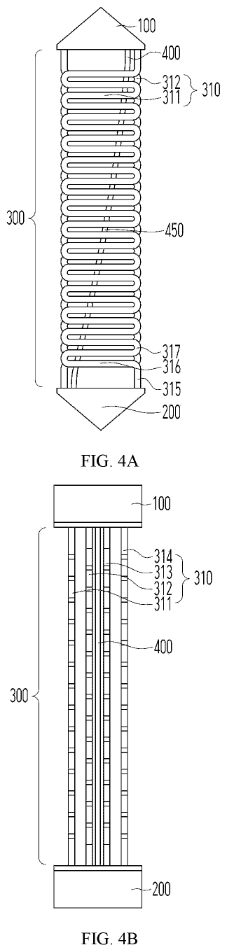

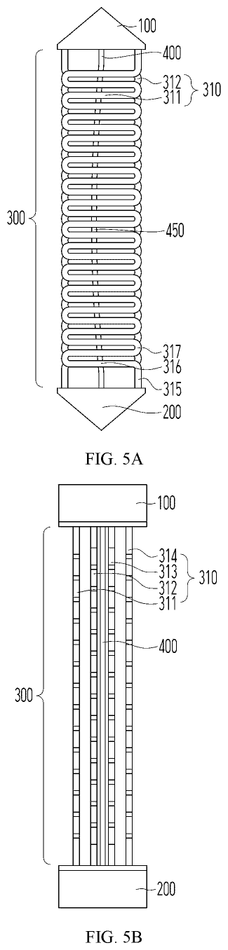

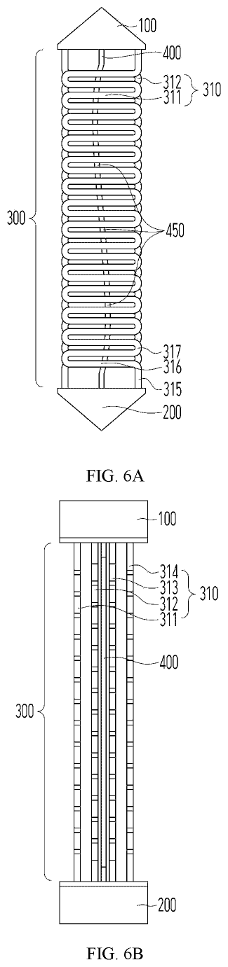

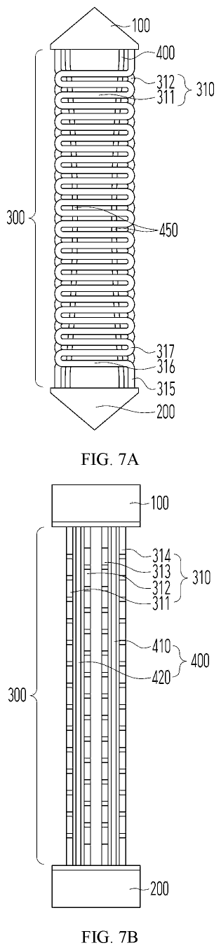

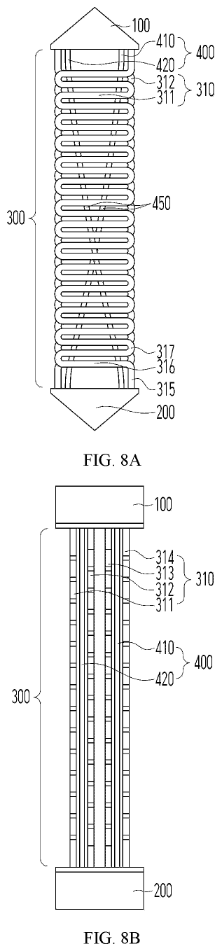

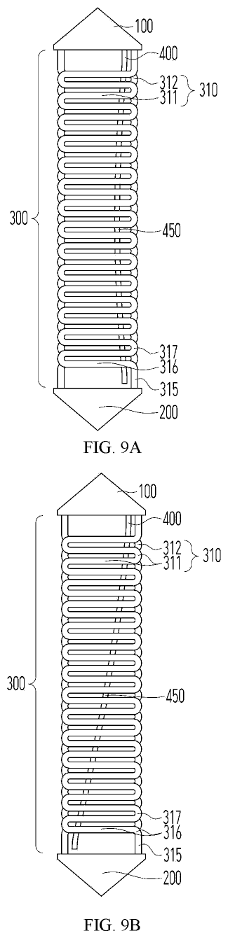

FIGS. 4A and 4B illustrate an electrically conductive pin 10 including a current transmission portion 400 according to an embodiment of the present invention. FIGS. 5A and 5B illustrate an electrically conductive pin 10 including a current transmission portion 400 according to an embodiment of the present invention. FIGS. 6A and 6B illustrate an electrically conductive pin 10 including multiple bent regions 450 according to an embodiment of the present invention. FIGS. 7A and 7B illustrate an electrically conductive pin 10 including multiple current transmission portions 400 according to an embodiment of the present invention. FIGS. 8A and 8B illustrate an electrically conductive pin 10 including multiple current transmission portions 400 according to an embodiment of the present invention. FIGS. 9A and 9B illustrate an electrically conductive pin 10 in which the current transmission portion 400 and the second contact portion 200 are spaced apart according to an embodiment of the present invention.

Referring to FIG. 3A, in an embodiment of the present invention, the current transmission portion 400 may have one end connected to one side in the width direction of the first contact portion 100 and the other end connected to one side in the width direction of the second contact portion 200. Here, one side in the width direction may refer to a position closer to the end of the first contact portion 100 encountered when proceeding in the width direction from the center. Here, one side in the width direction of the first contact portion 100 and one side in the width direction of the second contact portion 200 may refer to positions with the same y-axis coordinate.

Referring to FIG. 3B, in an embodiment of the present invention, the current transmission portion 400 may be located between the second elastic member 312 and the third elastic member 313. However, the position of the current transmission portion 400 is not limited to the aforementioned position, and the current transmission portion 400 may be located between at least one pair of elastic members 310 that are closely or adjacently arranged among the multiple elastic members 310.

Referring to FIG. 4A, in an embodiment of the present invention, the current transmission portion 400 may have one end connected to one side in the width direction of the first contact portion 100 and the other end connected to the other side in the width direction of the second contact portion 200. Here, one side in the width direction of the first contact portion 100 and the other side in the width direction of the second contact portion 200 may refer to positions equidistant from the center in opposite directions along the xz-plane in the width direction.

Referring to FIG. 4B, in an embodiment of the present invention, the current transmission portion 400 may be located between the second elastic member 312 and the third elastic member 313. However, the position of the current transmission portion 400 is not limited to the aforementioned position, and the current transmission portion 400 may be located between at least one pair of elastic members 310 that are closely or adjacently arranged among the multiple elastic members 310.

Referring to FIG. 5A, in an embodiment of the present invention, the current transmission portion 400 may have one end connected to the center side in the width direction of the first contact portion 100 and the other end connected to the center side in the width direction of the second contact portion 200. Here, the center side in the width direction may refer to the central region in the width direction.

Referring to FIG. 5B, in an embodiment of the present invention, the current transmission portion 400 may be located between the second elastic member 312 and the third elastic member 313. However, the position of the current transmission portion 400 is not limited to the aforementioned position, and the current transmission portion 400 may be located between at least one pair of elastic members 310 that are closely or adjacently arranged among the multiple elastic members 310.

Referring to FIG. 6A, in an embodiment of the present invention, the current transmission portion 400 may include two bent regions 450 bent in the width direction in at least a part thereof. The two bent regions 450 may induce deformation of the current transmission portion 400 in opposite directions in the width direction. By inducing deformation of the current transmission portion 400 in the width direction, the two bent regions 450 can prevent contact with the elastic portion 300, which is spaced apart in the thickness direction.

Referring to FIG. 6B, in an embodiment of the present invention, the current transmission portion 400 may be located between the second elastic member 312 and the third elastic member 313. However, the position of the current transmission portion 400 is not limited to the aforementioned position, and the current transmission portion 400 may be located between at least one pair of elastic members 310 that are closely or adjacently arranged among the multiple elastic members 310.

Referring to FIG. 7A, in an embodiment of the present invention, the current transmission portion 400 may be provided in plurality. The first current transmission portion 410 may have one end connected to one side in the width direction of the first contact portion 100 and the other end connected to one side in the width direction of the second contact portion 200. The second current transmission portion 420 may have one end connected to the other side in the width direction of the first contact portion 100 and the other end connected to the other side in the width direction of the second contact portion 200.

Referring to FIG. 7B, in an embodiment of the present invention, the first current transmission portion 410 may be located between the third elastic member 313 and the fourth elastic member 314. The second current transmission portion 420 may be located between the first elastic member 311 and the second elastic member 312. However, the position of the current transmission portion 400 is not limited to the aforementioned positions, and the current transmission portion 400 may be provided between at least one pair of elastic members 310 that are closely or adjacently arranged among the plurality of elastic members 310.

Referring to FIG. 8A, in an embodiment of the present invention, the current transmission portion 400 may be provided in plurality. The first current transmission portion 410 may have one end connected to one side in the width direction of the first contact portion 100 and the other end connected to the other side in the width direction of the second contact portion 200. The second current transmission portion 420 may have one end connected to the other side in the width direction of the first contact portion 100 and the other end connected to one side in the width direction of the second contact portion 200.

Referring to FIG. 8B, in an embodiment of the present invention, the first current transmission portion 410 may be located between the third elastic member 313 and the fourth elastic member 314. The second current transmission portion 420 may be located between the first elastic member 311 and the second elastic member 312. However, the position of the current transmission portion 400 is not limited to the aforementioned positions, and the current transmission portion 400 may be provided between at least one pair of elastic members 310 that are closely or adjacently arranged among the plurality of elastic members 310.

Referring to FIGS. 9A and 9B, in an embodiment of the present invention, the current transmission portion 400 may have one end connected to one of the first contact portion 100 and the second contact portion 200, and the other end spaced apart from the remaining one of the first contact portion 100 and the second contact portion 200. The other end of the current transmission portion 400 may be connected to the remaining one when the elastic portion 300 is compressed.

The electrically conductive pin 10 according to an embodiment of the present invention may reduce the compressive force applied to the independently provided current transmission portion 400 at its ends by providing the current transmission portion 400 with a length shorter than the length occupied by the elastic portion 300 in its non-compressed state, thereby improving durability.

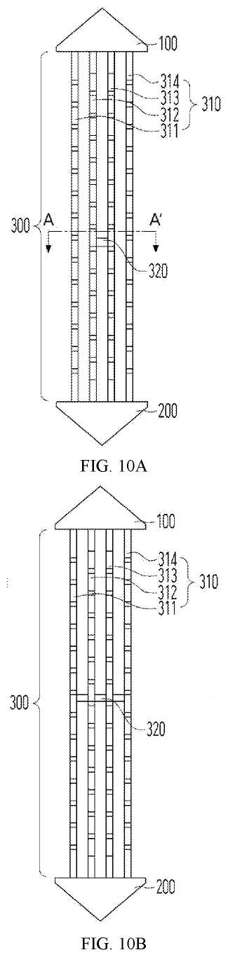

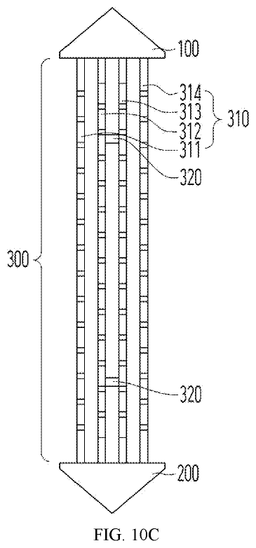

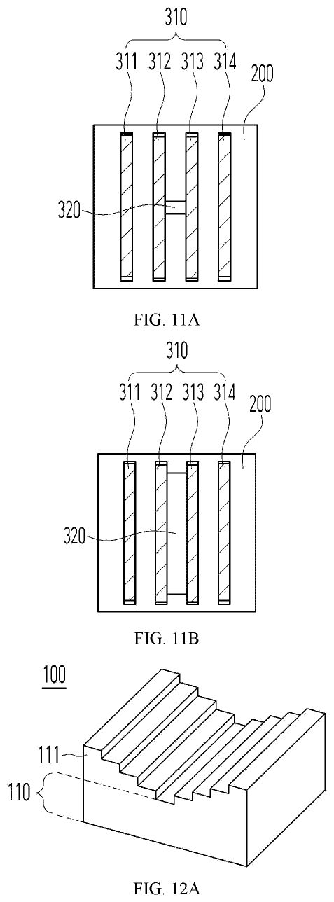

FIGS. 10A, 10B, and 10C are diagrams illustrating an electrically conductive pin 10 including a connecting member 320 according to an embodiment of the present invention. FIGS. 11A and 11B are diagrams illustrating the A-A′ cross-section of FIG. 10A.

Referring to FIGS. 10A to 10C, in an embodiment of the present invention, the elastic portion 300 may further include a connecting member 320 connecting at least two of the plurality of elastic members 310 to each other. The connecting member 320 may be provided between the plurality of elastic members 310. The connecting member 320 may be provided in plurality.

The electrically conductive pin 10 according to an embodiment of the present invention may improve physical properties by increasing the stability and durability of the elastic portion 300 through the connecting member 320 suppressing the independent deformation of the plurality of elastic members 310.

Referring to FIG. 10A, the connecting member 320 may be provided between the second elastic member 312 and the third elastic member 313 to suppress the independent deformation of the second elastic member 312 and the third elastic member 313, thereby inducing their simultaneous deformation. However, the position of the connecting member 320 is not limited to the position shown in FIG. 10A.

Referring to FIG. 10B, the connecting member 320 may be provided between the first elastic member 311 and the second elastic member 312, between the second elastic member 312 and the third elastic member 313, and between the third elastic member 313 and the fourth elastic member 314. The plurality of connecting members 320 may be located at the same height (same z-axis coordinate). The connecting member 320 may suppress the independent deformation of the first elastic member 311 to the fourth elastic member 314 and induce simultaneous deformation. However, the position of the connecting member 320 is not limited to the position shown in FIG. 10B.

Referring to FIG. 10C, the connecting member 320 may be provided in plurality at different positions between the second elastic member 312 and the third elastic member 313. However, the positions of the plurality of connecting members 320 are not limited to the positions shown in FIG. 10C.

Referring to FIG. 11A, in an embodiment of the present invention, the connecting member 320 may be formed on a part of the straight portion 316 (a single straight portion) of the elastic member 310 to connect the plurality of elastic members 310 spaced apart in the thickness direction. Referring to FIG. 11B, in an embodiment of the present invention, the connecting member 320 may be formed along the entire straight portion 316 of the elastic member 310 to connect the plurality of elastic members 310 spaced apart in the thickness direction. When the connecting member 320 is formed along the entire straight portion 316 (a single straight portion) of the elastic member 310, the structural stability of the elastic portion 300 may be further enhanced.

Next, various shapes of the first contact portion 100 and the second contact portion 200 will be examined.

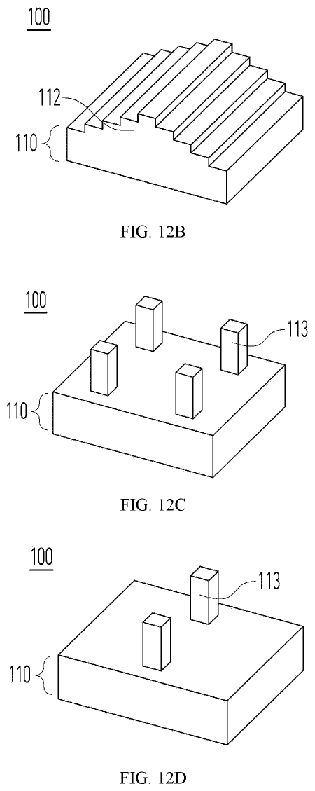

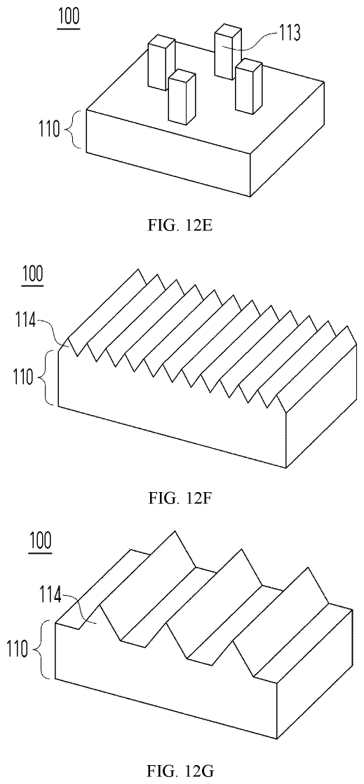

FIGS. 12A to 12G are diagrams illustrating the first contact portion 100 and/or the second contact portion 200 of the electrically conductive pin 10 according to various embodiments of the present invention.

Referring to FIGS. 12A to 12G, in an embodiment of the present invention, the electrically conductive pin 10 may include the first contact portion 100 and/or the second contact portion 200 of various shapes. Only the first contact portion 100 of the electrically conductive pin 10 may have the shape according to FIGS. 12A to 12G, only the second contact portion 200 may have the shape according to FIGS. 12A to 12G, or both the first contact portion 100 and the second contact portion 200 may have the shape according to FIGS. 12A to 12G.

At this time, the first contact portion 100 and the second contact portion 200 may be formed as a combination of different shapes. The first tip portion 111 to the fourth tip portion 114, which will be described later, may contact the inspection apparatus and/or the test object. The fixing portion 110 may support one or a plurality of tips 111, 112, 113, and 114. The first tip portion 111 to the fourth tip portion 114 may each be provided within the horizontal plane (xy-plane) of the fixing portion 110.

Referring to FIG. 12A, at least one of the first contact portion 100 and the second contact portion 200 may include a fixing portion 110 having a horizontal cross-sectional shape and size that remain constant along the longitudinal direction, and a first tip portion 111 having a lowest layer formed at the center in the width direction and a highest layer formed at the width direction ends, with multiple stepped layers formed in the width direction from the lowest layer to the highest layer.

At this time, the lowest layer may be provided as one, and the highest layer may be provided as two, with the two highest layers formed at the same height. The thickness and width of the first tip portion 111 may each be the same as the thickness and width of the fixing portion 110.

Referring to FIG. 12B, at least one of the first contact portion 100 and the second contact portion 200 may include a fixing portion 110 having a horizontal cross-sectional shape and size that remain constant along the longitudinal direction, and a second tip portion 112 having a highest layer formed at the center in the width direction and a lowest layer formed at the width direction ends, with multiple stepped layers formed in the width direction from the highest layer to the lowest layer.

At this time, the highest layer may be provided as one, and the lowest layer may be provided as two, with the two lowest layers formed at the same height. The thickness and width of the second tip portion 112 may each be the same as the thickness and width of the fixing portion 110.

Referring to FIGS. 12C to 12E, at least one of the first contact portion 100 and the second contact portion 200 may include a fixing portion 110 having a horizontal cross-sectional shape and size that remain constant along the longitudinal direction, and a third tip portion 113 having a horizontal cross-sectional size smaller than that of the fixing portion 110 and protruding from the fixing portion 110.

At this time, the third tip portion 113 may be provided in plurality, and the number and arrangement may be variously configured. For example, four (FIGS. 12C and 12E) or two (FIG. 12D) third tip portions 113 may protrude from the fixing portion 110 and be arranged spaced apart from each other. The thickness and width of one third tip portion 113 may each be smaller than the thickness and width of the fixing portion 110.

Referring to FIGS. 12F and 12G, at least one of the first contact portion 100 and the second contact portion 200 may include a fixing portion 110 having a horizontal cross-sectional shape and size that remain constant along the longitudinal direction, and a fourth tip portion 114 having a horizontal cross-sectional size smaller than that of the fixing portion 110, with the horizontal cross-sectional size gradually decreasing toward one longitudinal end and protruding from the fixing portion 110. The fourth tip portion 114 may have a tapered shape.

At this time, the fourth tip portion 114 may be provided in plurality, and the number and arrangement may be variously configured. For example, the plurality of fourth tip portions 114 may be arranged continuously (connected) along the width direction (FIG. 12F) or the thickness direction. Alternatively, the plurality of fourth tip portions 114 may be arranged spaced apart along the width direction (FIG. 12G) or the thickness direction. The thickness of one fourth tip portion 114 may be the same as the thickness of the fixing portion 110. The width (based on the maximum width) of one fourth tip portion 114 may be smaller than the width of the fixing portion 110.

However, the aforementioned shapes of the first contact portion 100 and the second contact portion 200 are merely examples and are not limited to the shapes shown in FIGS. 12A to 12G.

The electrically conductive pin 10 according to an embodiment of the present invention may correspond to electrode pads, bumps, etc., of various sizes and shapes by diversely applying the shapes of the first contact portion 100 and/or the second contact portion 200.

The present invention may improve the electrical characteristics of the electrically conductive pin 10 by forming a shorter current path than the elastic portion 300 through the current transmission portion 400.

The present invention may improve the physical characteristics of the electrically conductive pin 10 by including a curved current transmission portion 400, which is spaced apart from the elastic portion 300 in the thickness direction and simultaneously induces deformation in the width direction, thereby reducing friction between the current transmission portion 400 and the elastic portion 300.

The present invention can improve the physical characteristics of the conductive pin 10 by reducing friction between the plurality of elastic members 310, as the elastic portion 300 is provided with a plurality of elastic members 310 spaced apart from each other.

As described above, although the preferred embodiments of the present invention have been described with reference to the accompanying drawings, those skilled in the art may variously modify or change the present invention without departing from the spirit and scope of the invention as set forth in the following claims.

What is claimed is:

1. An electrically conductive pin provided in an inspection apparatus for checking whether a test object is defective and transmitting an electrical signal to the test object, the electrically conductive pin comprising:
a first contact portion located at one end of the electrically conductive pin;
a second contact portion located at the other end of the electrically conductive pin;
an elastic portion located between the first contact portion and the second contact portion and capable of compression and extension in a longitudinal direction; and
a current transmission portion spaced apart from the elastic portion in a thickness direction and located between the first contact portion and the second contact portion to transmit an electrical signal.

2. The electrically conductive pin of claim 1, wherein the elastic portion comprises:
a plurality of elastic members having one end and the other end connected to the first contact portion and the second contact portion, respectively, and spaced apart from each other in the thickness direction.

3. The electrically conductive pin of claim 2, wherein the elastic portion further comprises:
a connecting member connecting at least two of the plurality of elastic members to each other.

4. The electrically conductive pin of claim 1, wherein the current transmission portion comprises a bent region bent in a width direction in at least a portion thereof,
wherein the bent region induces deformation of the current transmission portion in the width direction.

5. The electrically conductive pin of claim 1, wherein the current transmission portion has one end connected to one side in a width direction of the first contact portion and the other end connected to one side in a width direction of the second contact portion.

6. The electrically conductive pin of claim 1, wherein the current transmission portion has one end connected to one side in a width direction of the first contact portion and the other end connected to the other side in a width direction of the second contact portion.

7. The electrically conductive pin of claim 1, wherein the current transmission portion has one end connected to a center side in a width direction of the first contact portion and the other end connected to a center side in a width direction of the second contact portion.

8. The electrically conductive pin of claim 1, wherein the current transmission portion comprises:
a first current transmission portion having one end and the other end connected to the first contact portion and the second contact portion, respectively; and
a second current transmission portion spaced apart from the first current transmission portion in the thickness direction and having one end and the other end connected to the first contact portion and the second contact portion, respectively.

9. The electrically conductive pin of claim 1, wherein the current transmission portion has one end connected to one of the first contact portion and the second contact portion,
the other end spaced apart from the other of the first contact portion and the second contact portion, and
the other end is connected to the other when the elastic portion is compressed.

10. The electrically conductive pin of claim 1, wherein the current transmission portion is made of a material having greater electrically conductivity than the elastic portion.
